(19) United States
(12) Patent Application Publication
(10) Pub. No.: US 2011/0290639 A1
(43) Pub. Date: Dec. 1, 2011

(54) METHOD AND APPARATUS FOR PROVIDING BEAMS OF NANODROPLETS FOR HIGH SPUTTERING RATE OF INERT MATERIALS

(75) Inventors: Manuel Gamero-Castano, Cerritos, CA (US); Mahesh Mahadevan, (US); R. Mahadeva Sarma, (US)

(73) Assignee: THE REGENTS OF THE UNIVERSITY OF CALIFORNIA, Oakland, CA (US)

(21) Appl. No.: 12/790,684

(22) Filed: May 28, 2010

(51) Int. Cl. C23C 14/34

(52) U.S. Cl. 204/192.34; 204/298.36

(57) ABSTRACT

A method for milling of a workpiece of inert material by nanodroplet beam sputtering includes the steps of providing a liquid; electrohydrodynamically atomizing the liquid to form charged nanodroplets; and directing the atomized charged nanodroplets onto the workpiece to selectively remove material. The method is used for broad-beam milling the workpiece of inert material, for precision micromachining and/or for three dimensionally profiling organic samples via secondary ion mass spectrometry. The liquid is electrosprayed in a cone-jet mode in a vacuum and average nanodroplet diameter, nanodroplet velocity, and molecular energy of the nanodroplets is adjusted by changing liquid flow rate and the acceleration voltage applied to the ionic liquid as it is atomized. Apparatus for performing the method are also included embodiments.

### BACKGROUND OF THE INVENTION

1. Field of the Invention

The invention relates to the field of methods and apparatus for providing nanodroplet beams for manufacturing and analytical applications (e.g. ion beam milling, focused ion beam micromachining, and three dimensional profiling of organic samples via secondary ion mass spectrometry).

2. Description of the Prior Art

It is known to use electrosprayed nanodroplets as projectiles for secondary ion mass spectrometry. It has also been proposed to use beams of electrosprayed droplets for the cleaning of surfaces. See, U.S. Pat. No. 6,768,119 B2, “Method and apparatus to produce ions and nanodrops from Taylor cones at reduced pressure”, by J. Fernandez de la Mora et. al. The art has developed a method to produce beams of nanodroplest, and to use these beams for the modification of surfaces. However, there is no known use of electrosprayed nanodroplet beams for the high sputtering rate of inert materials, nor the use of focused electrospray beams for precision micromachining or three dimensional profiling of organic samples via secondary ion mass spectrometry.

Ion beam milling (IBM) is a subtractive manufacturing technique used to carve features with high aspect ratios. Based on physical sputtering, the etching rates of IBM are lowest among subtractive techniques because of its beam's low molecular flux, which is limited by the space charge that develops between the plasma and accelerator screens. Maximum current densities produced by gridded, broadbeam ion sources typically range from 1-4 mA/cm². Although faster subtractive techniques such as reactive ion etching are used for dry, anisotropic etching on many substrates of interest, inert materials such as SiC and B₄C offer great resistance to chemical attack, and for them, IBM with its slow rate is a competitive option.

Previously, electrosprayed glycerol-based solutions have been used in a vacuum to produce charged nanodroplets, which are then used as projectiles for secondary ion mass spectrometry (SIMS). Like cluster ions, these large nanodroplets could desorb large macromolecules from both liquid and solid matrices. Organic samples can be analyzed via SIMS using cluster ion beams and charged nanoparticles. Beams of small ions have a tendency to fragment the large molecules typical of organic samples, while the larger cluster ions and nanoparticle projectiles can desorb and ionize large molecules without fragmentation. Furthermore, the damage caused by these large projectiles is confined to molecular layers on the surface, and therefore it is possible to do depth profiling with these beams. Unfortunately, cluster ion sources are not point sources and therefore these beams cannot be focused on a small spot. Thus, cluster ion sources do not have lateral resolution. What is needed is a source of nanoparticle projectiles that is amenable to focusing would enable three dimensional profiling of organic samples via SIMS.

Others have employed these energetic nanodroplets for surface cleaning. More recently, some researchers have resumed the research on electrosprayed nanodroplets as projectiles for SIMS. They atomize water-based solutions at atmospheric conditions, and introduce a fraction of the nanodroplets inside the vacuum chamber housing the analyte and a mass spectrometer.

### BRIEF SUMMARY OF THE INVENTION

We have recently shown that electrosprayed nanodroplets accelerated in a vacuum by a potential difference of the order of ten kilovolts, and impacting on a Si wafer, release a number of Si atoms comparable to the number of molecules in the droplet. The phenomenology of nanodroplet sputtering is similar to that of cluster ion beams, but a major difference is the method used to produce the projectiles: namely electrohydrodynamic atomization of a liquid in the case of charged nanodroplets versus homogeneous nucleation and condensation of a gas into clusters followed by ionization with an electron beam. The atomization parameters can be adjusted to produce droplets with average diameters ranging from a few to hundreds of nanometers. Therefore these projectiles are typically larger than cluster ions.

A beam of charged nanodroplets is produced in vacuum using an electrospray source operating in the cone-jet mode. The droplets are accelerated with an electrostatic field, and directed against a solid surface, e.g. a silicon carbide target. We measure high sputtering yields and very high sputtering rates. This embodiment can be implemented in broad-beam applications for flood manufacturing, and focused beam applications for precision micromachining and secondary ion mass spectrometry (SIMS) of organic samples.

Furthermore, the slow rate of physical sputtering using IBM can be improved by replacing the small atomic ions of IBM with cluster ions or in this case with charged nanodroplets. These massive projectiles have much lower charge to mass ratios, and significantly increase the beam molecular flux at the current densities capped by space charge. The illustrated embodiments present measurements of the sputtering yield and sputtering rate of Si, SiC, and B₄C substrates bombarded by a beam of electrosprayed nanodroplets at normal incidence. However, it is to be expressly understood that any other material, including inert materials, may be used as the target or workpiece according the scope of the invention. Below we describe the experimental methodology and the characterization of the beams. Then we present the sputtering results and a discussion of the findings.

The illustrated embodiments of the invention can be summarized a a method for milling of a workpiece of inert material by beam sputtering including the steps of providing an ionic liquid or any other dielectric liquid amenable to electrospraying in vacuo (e.g. formamide, propylene carbonate, etc.), electrohydrodynamically atomizing the liquid to form charged nanodroplets, and directing the atomized charged nanodroplets onto the workpiece to selectively remove material.

The step of directing the atomized charged nanodroplets onto the workpiece to selectively remove material comprises the step of arranging the emitters in a high density array, for broad-beam milling the workpiece of inert material.

The step of directing the atomized charged nanodroplets onto the workpiece to selectively remove material comprises the step of forming a beam of the atomized charged nanodroplets and electrostatic focusing it onto the workpiece for precision micromachining.

The step of directing the atomized charged nanodroplets onto the workpiece to selectively remove material further comprises the step of three dimensionally profiling organic samples via secondary ion mass spectrometry.

The step of electrohydrodynamically atomizing the liquid to form charged nanodroplets comprises electrospraying the liquid in a cone-jet mode in a vacuum.

The step of electrohydrodynamically atomizing the liquid to form charged nanodroplets comprises adjusting average nanodroplet diameter, nanodroplet velocity, and molecular energy of the nanodroplets by changing liquid flow rate and the acceleration voltage applied to the ionic liquid as it is atomized.

The step of adjusting molecular energy of the nanodroplets comprises imparting molecular energy to the nanodroplets substantially in excess of the bonding energies of the constituents of the target.

The step of electrohydrodynamically atomizing the liquid to form charged nanodroplets comprises generating a beam of nanodroplets having hypervelocity impact on the workpiece.

The method further includes the step of removing material from the workpiece at a rate in excess of 100 times greater than a broad ion beam source.

The method further includes the step of electrostatically focusing the beam of nanodroplets to provide focused-beam for precision micromachining.

The further includes the step of electrostatically focusing the beam of nanodroplets and performing three-dimensional SIMS-imaging of organic samples.

The scope of the invention includes apparatus for performing each of the above embodiments of the method. For example, the illustrated embodiments include an apparatus for milling of a workpiece of inert material by beam sputtering comprising an electrospray emitter, an electrohydrodynamic atomizer to form charged nanodroplets from the liquid, and an electrostatic lens to direct the atomized charged nanodroplets onto the workpiece to selectively remove material.

While the apparatus and method has or will be described for the sake of grammatical fluidity with functional explanations, it is to be expressly understood that the claims, unless expressly formulated under 35 USC 112, are not to be construed as necessarily limited in any way by the construction of “means” or “steps” limitations, but are to be accorded the full scope of the meaning and equivalents of the definition provided by the claims under the judicial doctrine of equivalents, and in the case where the claims are expressly formulated under 35 USC 112 are to be accorded full statutory equivalents under 35 USC 112. The invention can be better visualized by turning now to the following drawings wherein like elements are referenced by like numerals.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

FIG. 1 is a diagram of an experimental setup wherein the illustrated embodiments of the invention are demonstrated.

FIG. 2a is a photograph, FIG. 2b a profile depiction, and FIG. 2c an Atomic Force Microscope (AFM) image of a Si target bombarded for 15 minutes with a beamlet of nanodroplets (V_{A}=14.1 kV, I_{E}=373 nA, <D>=24.3 nm, <v_{d}>=4.28 km/s, <Eₘ>=37.2 eV).

FIG. 3a is a photograph, FIG. 3b is a profile depiction, and FIG. 3c is an AFM image of a Si target bombarded for 15 minutes with a beamlet of nanodroplets (V_{A}=15.1 kV, I_{E}=253 nA, <D>=34.3 nm, <v_{d}>=5.81 km/s, <Eₘ>=68.4 eV).

FIG. 4a is a photograph, FIG. 4b is a profile depiction, and FIG. 4c is an AFM image of a SiC target bombarded for 15 minutes with a beamlet of nanodroplets (V_{A}=18.1 kV, I_{E}=253 nA, <D>=24.3 nm, <v_{d}>=6.36 km/s, <Eₘ>=82.0 eV).

FIG. 5a is a photograph, FIG. 5b is a profile depiction, and FIG. 5c is an AFM image of a B₄C target bombarded for 15 minutes with a beamlet of nanodroplets (V_{A}=18.1 kV, I_{E}=253 nA, <D>=24.3 nm, <v_{d}>=6.36 km/s, <Eₘ>=82.0 eV).

FIG. 6 is a graph of the sputtering yield in ejected atoms per EMIIm molecule of Si, SiC, and B₄C as a function of the average kinetic energy of the EMIIm molecule, and for two electrospray currents of 253 and 373 nA.

FIG. 7 is a graph of the sputtering rate in terms of the speed at which the substrate is carved for Si, SiC, and B₄C as a function of the acceleration voltage, and for two electrospray currents of 253 and 373 nA.

FIG. 8 is a perspective diagram of a dense array of emitters for broad beam milling.

FIG. 9 is a perspective diagram of a single emitter nanodroplet source with beam focusing for precision micromachining.

The invention and its various embodiments can now be better understood by turning to the following detailed description of the preferred embodiments which are presented as illustrated examples of the invention defined in the claims. It is expressly understood that the invention as defined by the claims may be broader than the illustrated embodiments described below.

### DETAILED DESCRIPTION OF THE ILLUSTRATED EMBODIMENTS

The produced beam of electrosprayed nanodroplets in the illustrated embodiments overcomes the problems of the prior art, because of their lower charge to mass ratio, the molecular fluxes of nanodroplet beams are orders of magnitude larger than those of ion beams at the same current density, and so are their sputtering rates. Furthermore, an electrospray source is a point source and a large fraction of its beam can be focused in a small spot using electrostatic lenses. Nanodroplet beams have molecular fluxes that are orders of magnitude larger than ion beams. This is due to the lower charge to mass ratio of the nanodroplets, which reduces the repulsive forces of the beam's space charge. Thus, the sputtering rates of nanodropet beams can be orders of magnitude larger than those of ion beams. In addition, an electrospray source is a point source and strong focusing of the beam in a submicrometric spot is possible.

In the illustrated embodiment, single-crystal silicon and polycrystalline silicon carbide and boron carbide were bombarded with a beam of electrosprayed nanodroplets at normal incidence. The acceleration voltage of the beam ranged between 9.13 and 20.13 kV. The kinetic energy of the nanodroplet molecules varied between 24.1 and 91.2 eV. The volume of sputtered material was measured with a profilometer, and the molecular flux of the beamlet with a time of flight spectrometer. Sputtering yields as high as 2.32, 1.48, and 2.29 atoms per molecule were obtained for Si, SiC, and B₄C. The maximum receding rates of the substrates' surfaces were 448, 172, and 170 nm/min respectively. The significant increase with respect to the sputtering rates of broad-beam atomic ion sources is due to the large molecular flux of electrosprays.

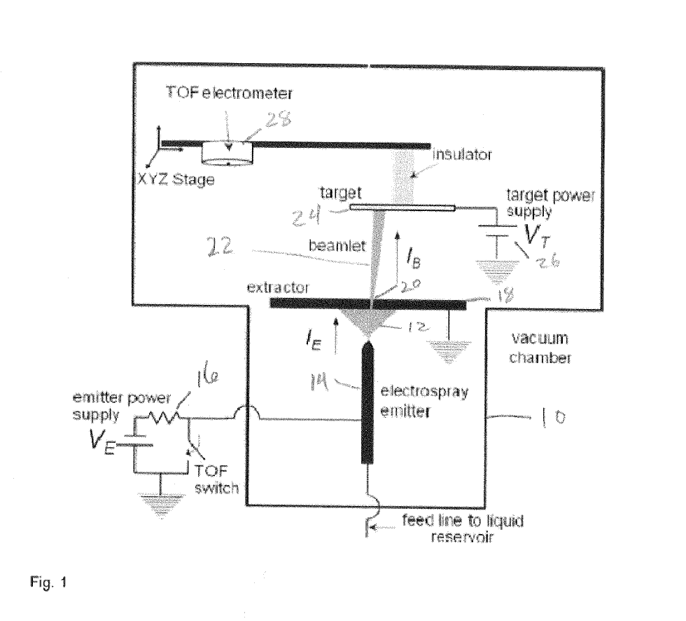

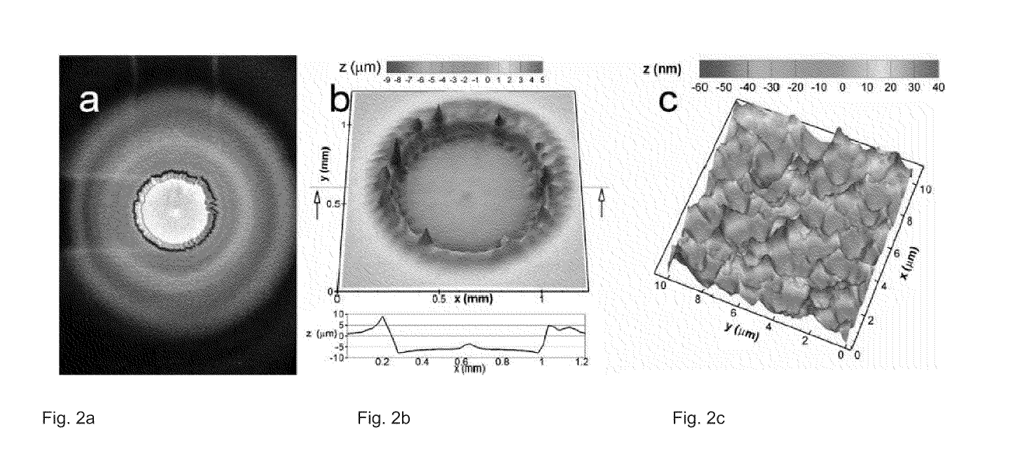

A beam of nanodroplets is produced with an electrospray source 14 &18 operating inside a vacuum chamber 10. FIG. 1 is a sketch of the experimental setup we have used to demonstrate the sputtering of ceramics by nanodroplet beams. FIGS. 2-5, discussed below, show the damage caused by the nanodroplet beam on silicon, silicon carbide and boron carbide targets. In this particular experiment we have used the ionic liquid 1-ethyl-3-methylimidazolium bis(trifluoromethylsulfonyl) imide (EMIIm) to produce the nanodroplets, but many other ionic liquids and other dielectric liquids can also be used. The experimental setup is shown in FIG. 1. The electrospray source 14 &18 operates inside a vacuum chamber, and produces a conical beam 12 of negatively charged droplets carrying a current I_{E}. The base pressure is 5×10−6 Torr. The electrospray emitter is a platinum tube 14 (0.16 mm inside diameter, 0.48 mm outside diameter) electrified at a potential V_{E}, typically −2130 V generated by an emitter power supply 16 with respect to a grounded facing extractor 18. A fraction of the electrospray escapes the emitter-extractor region through a small orifice 20 drilled in the extractor 18, and coaxial with the emitter 14. In an actual source this extracting orifice is larger and lets the whole beam pass through. The charge to mass ratio distribution f(ξ), the mass flow rate dm_{B}/dt, and the current I_{B} of the extracted beamlet 22 are measured with a time-of-flight analyzer 28.

Alternatively, the beamlet 22 is directed against a sputtering target 24 at electric potential V_{T} provided by target power supply 26. The acceleration voltage of the beamlet 22 is V_{A}=V_{T}−V_{E}. The velocity of a nanodroplet is v_{d}=(2ξV_{A})^{-1/2}. The kinetic energy of an EMIIm molecule is Eₘ=mₘv_{d}²/2=mₘξV_{A}, where mₘ is the molecular mass 391.12 amu. The pressure at the point of impact is of the order of P=ρv_{d}²=2 ρξV_{A}, where ρ is the liquid density, 1520 kg/m³. The electrospray current I_{E} is proportional to the square root of the liquid flow rate, which is a controllable parameter. The diameter and charge to mass ratio distributions of the droplets are functions of the liquid flow rate, or equivalently of I_{E}. The lower the electrospray current, the smaller the average droplet diameter and the larger the average charge to mass ratio.

In summary, the average diameter, nanodroplet velocity, and molecular energy can be adjusted by changing the liquid flow rate and the acceleration voltage. Table I contains relevant parameters of the beams used in this study.

TABLE I
Relevant parameters of the two nanodroplet beams used in this study: electrospray
current I_{E}, beamlet current I_{B}, beamlet mass flow rate m_{B}, average droplet
charge to mass ratio [symbol] ξ [symbol] , diameter [symbol] D [symbol] , number of molecules [symbol] Nₘ [symbol] , velocity [symbol]
v_{d} [symbol] ,molecular energy [symbol] Eₘ [symbol] , and impact pressure P. The last three parameters
are computed at the extreme values of the acceleration voltage, 20.13 and 9.13 kV.

| I_{E} | I_{B} | m_{B} | [symbol] ξ [symbol] | [symbol] D [symbol] | | [symbol] v_{d} [symbol] | [symbol] Eₘ [symbol] | P |
|---|---|---|---|---|---|---|---|---|
| (nA) | (nA) | (kg/s) | (C/kg) | (nm) | [symbol] Nₘ [symbol] | (km/s) | (eV) | (GPa) |
| 373 | 38.7 | 4.67 × 10⁻¹¹ | 650 | 34.8 | 51660 | 5.11 | 53.1 | 39.8 |
| | | | | | | 3.44 | 24.1 | 18.0 |
| 253 | 42.1 | 3.22 × 10⁻¹¹ | 1116 | 24.3 | 17520 | 6.70 | 91.2 | 68.3 |
| | | | | | | 4.51 | 41.4 | 31.0 |

The sputtering data were obtained at acceleration voltages between 9.13 and 20.13 kV, and for two values of the electrospray current, I_{E}=373 and 253 nA. The average diameters of the nanodroplets were estimated using the measured charge to mass ratio, and a charge level of 68% of the Rayleigh limit,

[symbol]

D [symbol] =0.68^{2/3}(288γ∈₀/ρ² [symbol] ξ [symbol] ²)^{1/3}. (1)

∈₀ is the permittivity of the vacuum, and γ the surface tension of the liquid, 0.0349 N/m. Average droplet velocities are in the 6.70-3.44 km/s range. The molecular energies and typical impact pressures associated with these two velocities are 91.2 eV, 68.3 GPa, 24.1 eV, and 18.0 GPa. The molecular energies are much larger than the bond energies of the pairs Si—Si, C—Si, and C—B (1.94, 3.01, and 3.24 eV), and therefore the nanodroplets have the potential to produce considerable damage to the crystalline substrates.

The sputtering yield is calculated with the formula

$$Y = \frac{{m}_{{ }_{m}}}{{\dot{m}}_{B} τ} \frac{{n}_{C} {ρ}_{C} V}{{m}_{C}} , \qquad ( 2 )$$

where V is the volume of material removed from the substrate, τ is the time of exposure to the beamlet, ρ_{C} is the density of the crystal (2330, 3200, and 2520 kg/m³ for Si, SiC, and B₄C), and mC and nC are the mass and number of atoms in a crystal cell (28.08 amu and 1 for Si, 40.10 amu and 2 for SiC, 55.25 amu and 5 for B₄C).

The position of the carved surface is determined with a profilometer, and its integration yields V. The sputtering rate is defined as

R=V/A_{τ} 3

The area A is the normal projection of the carved surface on the planar face of the substrate. The Si target is a 2-in., prime grade [100] wafer. The SiC and B₄C targets are 2-in. polycrystalline disks with purities better than 99.5%, and manufactured by Feldco International via hot pressing.

Consider now the results in the illustrated embodiment. FIGS. 2a-5c show photographs, profiles, and atomic force microscope images of Si, SiC, and B₄C substrates bombarded for 15 min. The line of sight of the microscope in all photographs is perpendicular to the surface, which is illuminated with polychromatic light at grazing angle. FIGS. 2a-2c are for the Si target, I_{E}=373 nA and V_{A}=14.1 kV. The center of the photograph of FIG. 2a shows a circular and bright area bombarded by the beamlet 22, and surrounded by iridescent rings. The brightness is due to the scattering of light by a rough surface, while the darkness of the outer corners is due to the lack of normal reflection from the polished wafer. The profilometer shows in FIG. 2b that the bombarded area is approximately 7 μm deep, and that the surrounding region rises above the original surface. The beamlet 22 removes silicon from the central area, and a fraction deposits nearby to form a thin film. The thickness of the film decreases at increasing separation from the depression. The colorful rings are produced by the interference of rays of light reflected from both the top of the film and the surface of the wafer below, coupled with the monotonic decrease of the film thickness. The image recorded by atomic force microscopy (AFM) shows in FIG. 2c that the carved surface is made of a multitude of intertwined craters with diameters of a few micrometers, and depths of a few tens of nanometers. The rms roughness is 19.4 nm. These micron-sized features are responsible for the strong scattering of light and brightness of the depression.

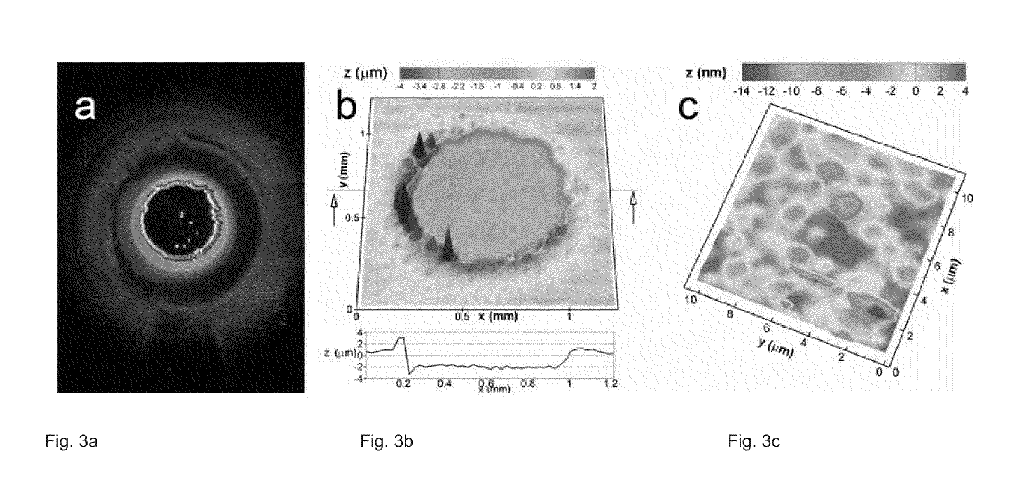

FIGS. 3a-3c are for the Si target, I_{E}=253 nA and V_{A}=15.1 kV. The depression carved by the beamlet 22 is approximately 2 μm deep, and has a specular surface as shown in FIG. 3b. The rms roughness of the surface in FIG. 3c is 2.9 nm. The volumes of both ejected silicon and deposits surrounding the depression are smaller than in FIG. 2c.

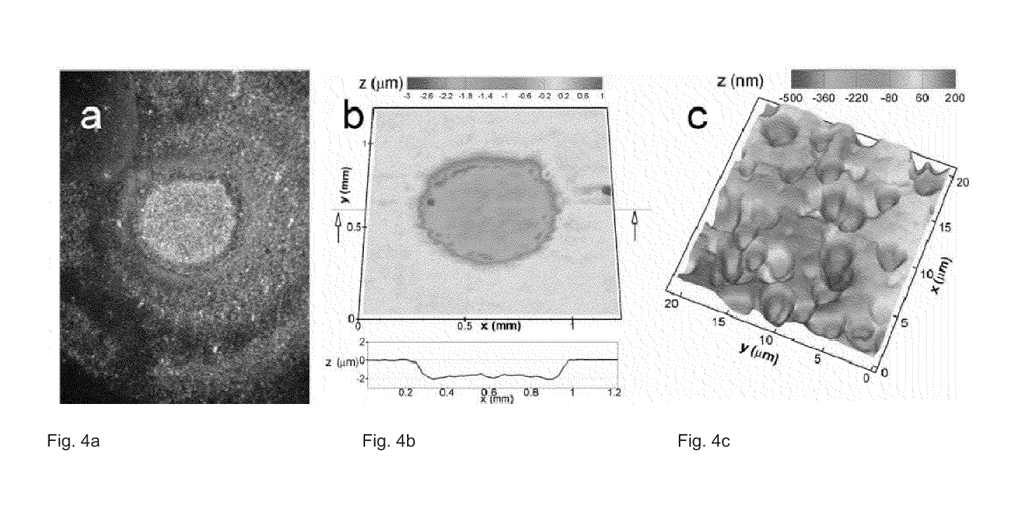

FIGS. 4a-4c are for the SiC target, I_{E}=253 nA and V_{A}=18.1 kV. The AFM image in FIG. 4c shows that the surface contains isolated micron-sized craters, surrounded by a smoother surface. The rms roughness is 160 nm. The depth of the depression is approximately 2 μm. There is no redeposition of sputtered material around the depression.

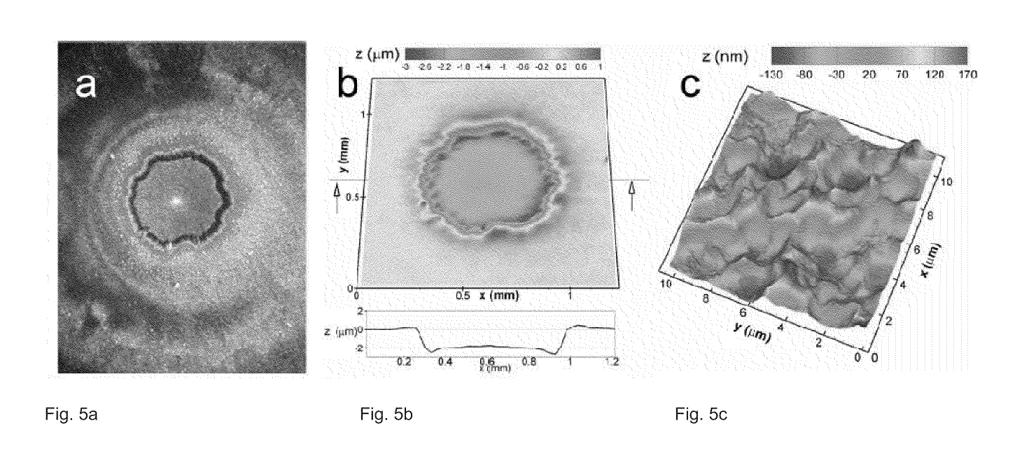

FIGS. 5a-5c are for the B₄C target, I_{E}=253 nA and V_{A}=19.1 kV. Similarly to the first Si target, the surface is made of superimposed micron-sized craters. The rms roughness of the surface in FIG. 5c is 63 nm. The depth of the depression is approximately 2 μm. There is a slight redeposition of sputtered material surrounding the depression.

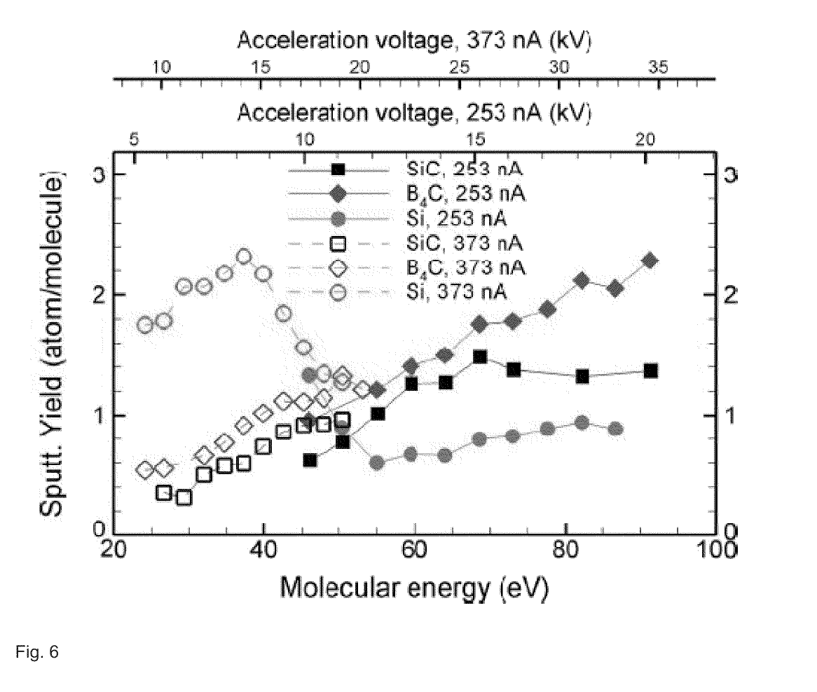

FIG. 6 plots the sputtering yield of Si, SiC, and B₄C as a function of the molecular energy and for the two electrospray currents. The values of the acceleration voltages are given in auxiliary axes. Silicon has the highest yields, especially when the damaged surface is covered by micron-sized craters. We have observed that, depending on the acceleration voltage and the electrospray current, the bombarded Si surface is either smooth (see FIG. 3b), or formed by micron-sized craters (see FIG. 2b). For a given electrospray current, i.e., at fixed average droplet diameter and charge to mass ratio, the beam starts damaging the surface at relatively low voltages (typically 7 kV), the sputtering yield increases with the acceleration voltage, and micron-sized craters dominate the sputtered surface. When the acceleration voltage surpasses a critical value, which depends on the average diameter and charge to mass ratio of the droplets, the craters disappear and a smooth surface is carved. At this point the sputtering yield drops significantly. The smaller the droplets, the lower the acceleration voltage associated with the transition between the rough and specular surfaces.

For example, the transition occurs around V_{A}=15 kV for I_{E}=373 nA, and near V_{A}=10 kV for I_{E}=253 nA. The sputtered surfaces of SiC and B₄C always contain micron-sized craters, at least within the range of acceleration potentials studied in this disclosure. In the crater-sputtering mode the yield appears to be an increasing function of the molecular energy: beams with different average droplet diameters and acceleration voltages but equal molecular energy have similar sputtering yields.

The maximum sputtering yields in FIG. 6 are 2.32, 1.48, and 2.29 atoms per molecule for Si, SiC, and B₄C respectively; the energies of the EMIIm molecules are 37.3, 68.7, and 91.2 eV, respectively. The sputtering yields of Si, SiC, and B₄C bombarded by argon at normal incidence and 500 eV are 0.4, 0.8, and 0.2 atoms per ion.

An accurate determination of the threshold voltage for sputtering is not possible in our setup of FIG. 1. A beamlet 22 carries nanodroplets with different molecular energies because of the broad distribution of charge to mass ratio existing at any electrospray current. This variance of energies is especially problematic at the low acceleration voltages that start causing surface damage (typically 7 kV). Some droplets are energetic enough to sputter, while others cannot and form a layer of liquid on the surface. We have observed that this liquid deposit prevents the sputtering by the more energetic droplets. The scope and spirit of the invention, however, contemplates that the threshold voltage for sputtering could be accurately determined by conventional means known in the art and employed to control the disclosed method.

We do not know whether the Im− anions and EMI+ cations making up the projectiles fragment into atoms upon impact. These are stable molecules with strong covalent bonds. Previous work by others using glycerol nanodroplets with impact velocities comparable to ours does not show fragmentation of glycerol molecules. It is worth noting that the velocity and impact pressure of these nanodroplets are typical of hypervelocity impact, and that both types of collisions can produce craters many times larger than the size of the projectiles. The field of hypervelocity impact deals with macroprojectiles, and length scales for which the solid target can be treated as a continuum with macro strain-stress properties. However, at the scale of a nanodroplet, a material such as monocrystalline silicon has very few dislocations, its strain-stress relation nears that of a perfect crystal, and the carving of a crater orders of magnitude larger than the projectile seems unfeasible. In fact, we have observed in silicon targets that micron-sized craters are formed only after an initial exposure time of approximately three minutes. Before this, shallow indentations of the order of the droplet size are formed. We think that most nanodroplets eject a volume of silicon comparable to its own, and at the same time create defects on the crystalline structure. The accumulation of defects would weaken the surface, and make it possible for impacts to occasionally produce micron-sized craters.

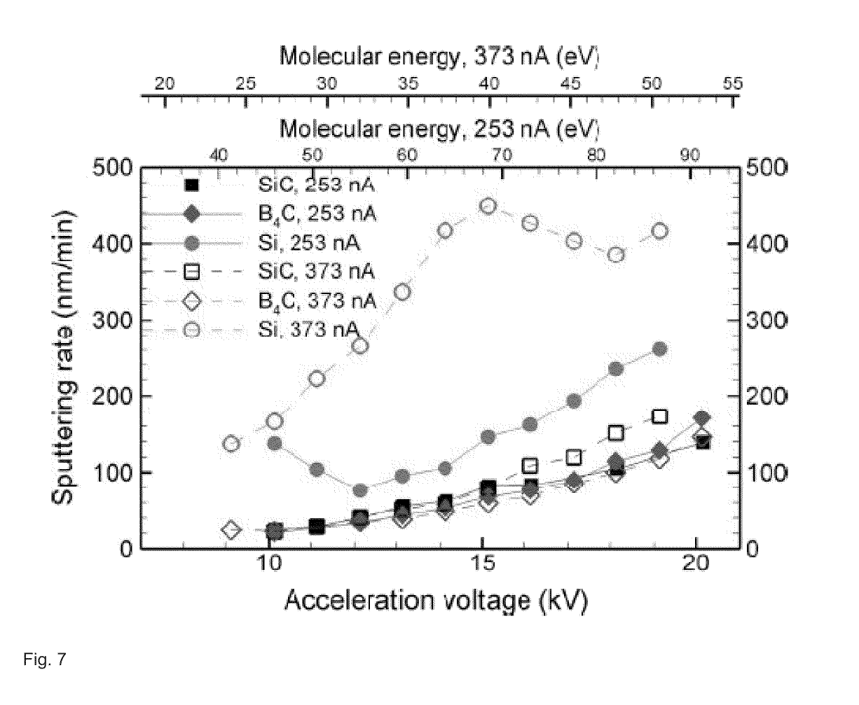

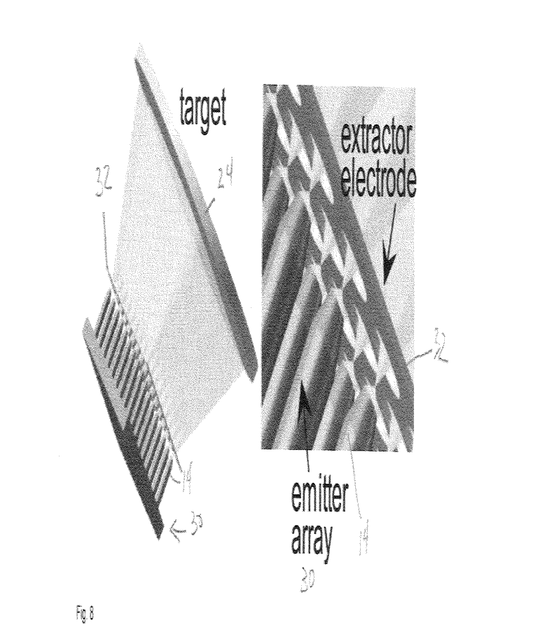

FIG. 7 shows the sputtering rate as a function of the acceleration voltage. The sputtering rate increases with V_{A} faster than the yield because the beamlets become narrower at increasing acceleration voltage, and therefore carve smaller areas (see Eq. (3)). The maximum sputtering rates for Si, SiC, and B₄C are 448, 172, and 170 nm/min. The associated current densities at the target are 9.26×10⁻³, 1.55×10⁻², and 1.33×10⁻² mA/cm², respectively. It is worth comparing these values with those of gridded, broadbeam ion sources. A typical broad-beam ion source operates with argon at a current density of 2 mA/cm² and 500 V acceleration voltage. The space charge that forms between the plasma and the extraction grids imposes a fundamental limit on the current density and thus on the projectile flux, while energy values of the order of 1000 eV and larger cause ion implantation and undesired surface damage. Under these conditions a gridded ion source has sputtering rates of 60, 62, and 11 nm/min for Si, SiC, and B₄C, which are significantly smaller than those of nanodroplets. Furthermore, the current densities and sputtering rates of nanodroplet beams could be made much larger than the values in this disclosure if a micromachined electrospray source with densely packed emitters 14 were employed, such as those illustrated in FIG. 8, where an array 30 of emitters 14 are combined with an extractor 32 having an atomizing orifice corresponding to each emitter 14 in the array 30.

The use of the term sputtering to describe the ejection of material by energetic nanodroplets may require a justification. Traditionally, sputtering refers to the removal of surface atoms by the mechanism of cascade collisions, induced by energetic ions penetrating the surface. More recently, larger projectiles such as cluster ions have been used to alter surfaces. Cluster ions with diameters of a few nanometers carve craters several times their size, do not necessarily penetrate into the substrate, and thermalization as well as cascade collisions processes play roles in the emission. Despite these differences, the surface damage caused by cluster ions is commonly referred to as sputtering. Electrosprayed nanodroplets overlap with and extend the size range of cluster ions. However, the use of the same label for these energetic projectiles should not lead to the confusion that the mechanism for their use is identical.

In conclusion, the maximum sputtering yields of Si, SiC, and B₄C bombarded by electrospray nanodroplets are larger than one. These yields, combined with the high molecular flux of a single electrospray source, produce sputtering rates as high as 448, 172, and 170 nm/min, respectively. Depending on the substrate material, the size of the nanodroplets and the acceleration potential, the features carved on the surface vary from shallow indentations comparable to the size of the nanodroplets, to micron-sized craters. Thus, the rms roughness of the bombarded surface ranges from a few to hundreds of nanometers, resulting in the formation of both specular and diffusive surfaces.

The advantages of the illustrated embodiments includes the ability to perform broad-beam milling of inert materials: a broad beam with increased molecular flux is produced by an electrospray source with a dense emitter array. The broad beam is used to sputter large areas of a substrate. We estimate that a sputtering rate 500 times higher than that of the state of the art broad ion beam source is possible. This improvement would be most important for the bulk machining of inert materials such as silicon carbide, boron carbide and silicon nitride, which resist chemical attack and for which fast reactive ion etching processes do not exist.

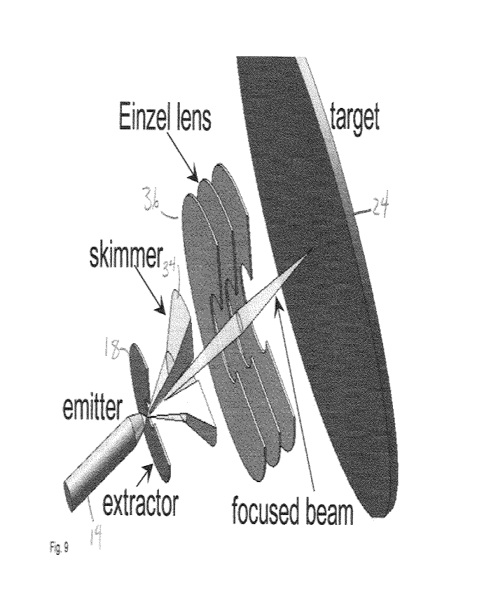

Another advantages of the illustrated embodiments includes focused-beam for precision micromachining. The possibility for beam focusing, combined with the large molecular flux of a nanodroplet beam, lead to an application similar to liquid metal ion source-focused ion beam, but with much larger sputtering rates. FIG. 9 illustrates one embodiment where emitter 14 and extractor 18 of FIG. 1 are further combined with a skimmer 34 for refining the beam together with an Einzel lens 36 to provide a focused beam on the target or workpiece.

Yet another advantages of the illustrated embodiments includes three dimensional profiling of organic samples via secondary ion mass spectrometry. Electrosprayed nanodroplets have several desired properties for SIMS projectiles. Others have shown that electrosprayed glycerol nanodroplets produce high yields of secondary ions from biological samples, with and without the assistance of a liquid matrix. These others were able to desorb molecules as large as cytochrome c (12361 Da) with negligible fragmentation. More recently, researchers have found that electrosprayed water nanodroplets produce atomic and molecular layer-by-layer etching of SIMS organic samples. These properties of electrosprayed nanodroplets, combined with the expected capability for beam focusing in submicrometric spots, would make it possible to do three-dimensional SIMS-imaging of organic samples (focusing provides lateral resolution, while the molecular layer-by-layer etching provides depth resolution)

a. Many alterations and modifications may be made by those having ordinary skill in the art without departing from the spirit and scope of the invention. Therefore, it must be understood that the illustrated embodiment has been set forth only for the purposes of example and that it should not be taken as limiting the invention as defined by the following invention and its various embodiments.

Therefore, it must be understood that the illustrated embodiment has been set forth only for the purposes of example and that it should not be taken as limiting the invention as defined by the following claims. For example, notwithstanding the fact that the elements of a claim are set forth below in a certain combination, it must be expressly understood that the invention includes other combinations of fewer, more or different elements, which are disclosed in above even when not initially claimed in such combinations. A teaching that two elements are combined in a claimed combination is further to be understood as also allowing for a claimed combination in which the two elements are not combined with each other, but may be used alone or combined in other combinations. The excision of any disclosed element of the invention is explicitly contemplated as within the scope of the invention.

The words used in this specification to describe the invention and its various embodiments are to be understood not only in the sense of their commonly defined meanings, but to include by special definition in this specification structure, material or acts beyond the scope of the commonly defined meanings. Thus if an element can be understood in the context of this specification as including more than one meaning, then its use in a claim must be understood as being generic to all possible meanings supported by the specification and by the word itself.

The definitions of the words or elements of the following claims are, therefore, defined in this specification to include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements in the claims below or that a single element may be substituted for two or more elements in a claim. Although elements may be described above as acting in certain combinations and even initially claimed as such, it is to be expressly understood that one or more elements from a claimed combination can in some cases be excised from the combination and that the claimed combination may be directed to a subcombination or variation of a subcombination.

Insubstantial changes from the claimed subject matter as viewed by a person with ordinary skill in the art, now known or later devised, are expressly contemplated as being equivalently within the scope of the claims. Therefore, obvious substitutions now or later known to one with ordinary skill in the art are defined to be within the scope of the defined elements.

The claims are thus to be understood to include what is specifically illustrated and described above, what is conceptionally equivalent, what can be obviously substituted and also what essentially incorporates the essential idea of the invention.

We claim:

1. A method for milling of a workpiece by beam sputtering comprising:
providing a liquid;
electrohydrodynamically atomizing the liquid to form charged nanodroplets; and
directing the atomized charged nanodroplets onto the workpiece to selectively remove material.

2. The method of claim 1 where directing the atomized charged nanodroplets onto the workpiece to selectively remove material comprises using a high density array of emitters for broad-beam, flood manufacturing of large workpieces.

3. The method of claim 1 where directing the atomized charged nanodroplets onto the workpiece to selectively remove material comprises forming a beam of the atomized charged nanodroplets and focusing them with electrostatic lenses onto the workpiece for precision micromachining.

4. The method of claim 1 where directing the atomized charged nanodroplets onto the workpiece to selectively remove material further comprises three dimensionally profiling organic samples via secondary ion mass spectrometry.

5. The method of claim 1 where providing an ionic liquid, or nonionic liquid suitable for electrospray atomization in vacuo).

6. The method of claim 1 where electrohydrodynamically atomizing the liquid to form charged nanodroplets comprises electrospraying the ionic liquid in a cone-jet mode in a vacuum.

7. The method of claim 1 where electrohydrodynamically atomizing the liquid to form charged nanodroplets comprises adjusting average nanodroplet diameter, nanodroplet velocity, and molecular energy of the nanodroplets by changing liquid flow rate and the acceleration voltage applied to the ionic liquid as it is atomized.

8. The method of claim 7 where adjusting molecular energy of the nanodroplets comprises imparting molecular energy to the nanodroplets substantially in excess of bonding energies of the constituents of the workpiece.

9. The method of claim 1 further comprising removing material from the workpiece at a rate in excess of 100 times greater than a broad ion beam source.

10. The method of claim 1 further comprising electrostatically focusing the beam of nanodroplets to provide focused-beam for precision micromachining.

11. The method of claim 1 further comprising electrostatically focusing the beam of nanodroplets and performing three-dimensional SIMS-imaging of organic samples.

12. An apparatus for milling of a workpiece of inert material by beam sputtering comprising:
an electrospray emitter for a liquid;
an electrohydrodynamic atomizer to form charged nanodroplets from the liquid; and
an electrostatic lens to direct the atomized charged nanodroplets onto the workpiece to selectively remove material for precision micromachining applications.

13. The apparatus of claim 12 where the emitter comprises a multiemitter electrospray source for broad beam applications.

14. The apparatus of claim 13 where the multiemitter electrospray source comprises a broad-beam mill.

15. The apparatus of claim 13 where the emitter, atomizer and electrostatic lens are arranged and configured to comprise a precision micromachining device.

16. The apparatus of claim 13 in combination with a secondary ion mass spectrometer and where the emitter, atomizer and electrostatic lens are arranged and configured to extract ions from an organic surface, for three dimensional profiling of the surface composition via secondary ion mass spectrometry.

17. The apparatus of claim 13 where the atomizer is an electrospray emitter operating in a cone-jet mode inside a vacuum.
